(19) United States
(12) Patent Application Publication
(10) Pub. No.: US 2025/0364508 A1
(43) Pub. Date: Nov. 27, 2025

(54) SEMICONDUCTOR PACKAGE AND METHOD FOR MAKING THE SAME

(71) Applicant: STATS ChipPAC Pte. Ltd., Singapore (SG)

(72) Inventors: TaeWoo LEE, Incheon (KR); HeeSoo LEE, Incheon (KR); EunHee MYUNG, Gyeonggi-do (KR)

(21) Appl. No.: 19/218,621

(22) Filed: May 27, 2025

(30) Foreign Application Priority Data
May 27, 2024 (CN) 202410665061.3

(51) Int. Cl. H01L 25/16; H01L 23/31; H01L 23/48; H01L 23/538; H01L 25/00

(52) U.S. Cl. CPC H01L 25/16; H01L 23/3128; H01L 23/3157; H01L 23/481; H01L 23/5386; H01L 25/50

(57) ABSTRACT

A semiconductor package comprises: a substrate comprising a substrate interconnection structure; a base semiconductor die comprising a plurality of through vias at a periphery of the base semiconductor die and extending between a top surface and a bottom surface of the base semiconductor die, each electrically coupled to the substrate; at least one first semiconductor component disposed beside the base semiconductor die, wherein the base semiconductor die is electrically connected to the at least one first semiconductor component via the substrate interconnection structure; an encapsulant layer for encapsulating the at least one first semiconductor component and the base semiconductor die but exposing the top surface of the base semiconductor die; and at least one second semiconductor component disposed on the top surface of the base semiconductor die and the encapsulant layer, and electrically coupled to the substrate through at least one of the plurality of through vias.

### TECHNICAL FIELD

The present application generally relates to semiconductor technology, and more particularly, to semiconductor packages and a method for making semiconductor packages.

### BACKGROUND OF THE INVENTION

Semiconductor devices are commonly found in modern electronic products, which perform a wide range of functions, such as signal processing, high-speed computation, transmitting and receiving electromagnetic signals, controlling electronic devices, and creating visual images for video displays. With the continued improvement in electronic products, it is desired to integrate more and more electronic components in a single package. For example, a semiconductor die may be integrated with multiple memory dice. However, the spatial efficiency of the current layout in a semiconductor package may be limited.

Therefore, there is a need for an improved packaging technology for semiconductor devices with multiple electronic components.

### SUMMARY OF THE INVENTION

An objective of the present application is to provide a semiconductor package with improved spatial efficiency.

According to an aspect of the present application, a semiconductor package is provided. The semiconductor package comprises: a substrate comprising a substrate interconnection structure; a base semiconductor die comprising a plurality of through vias at a periphery of the base semiconductor die and extending between a top surface and a bottom surface of the base semiconductor die, wherein each of the plurality of through vias is electrically coupled to the substrate; at least one first semiconductor component disposed beside the base semiconductor die and on the substrate, wherein the base semiconductor die is electrically connected to the at least one first semiconductor component via the substrate interconnection structure; an encapsulant layer for encapsulating the at least one first semiconductor component and the base semiconductor die but exposing the top surface of the base semiconductor die; and at least one second semiconductor component each being disposed on the top surface of the base semiconductor die and the encapsulant layer, and electrically coupled to the substrate through at least one of the plurality of through vias.

According to another aspect of the present application, a method for making a semiconductor package is provided. The method comprises: providing a substrate, wherein the substrate comprises a substrate interconnection structure; mounting at least one first semiconductor component on the substrate; mounting a base semiconductor die on the substrate and beside the at least one first semiconductor component to electrically couple the base semiconductor die with the at least one first semiconductor component via the substrate interconnection structure, wherein the base semiconductor die comprises a plurality of through vias at a periphery of the base semiconductor die and extending between a top surface and a bottom surface of the base semiconductor die; forming an encapsulant layer on the substrate to encapsulate the at least one first semiconductor component and the base semiconductor die but expose the top surface of the semiconductor die; and mounting at least one second semiconductor component on the base semiconductor die and on the encapsulant layer to electrically couple the at least one second semiconductor component with the base semiconductor die through at least one of the plurality of through vias.

It is to be understood that both the foregoing general description and the following detailed description are exemplary and explanatory only, and are not restrictive of the invention. Further, the accompanying drawings, which are incorporated in and constitute a part of this specification, illustrate embodiments of the invention and together with the description, serve to explain principles of the invention.

### BRIEF DESCRIPTION OF DRAWINGS

The drawings referenced herein form a part of the specification. Features shown in the drawing illustrate only some embodiments of the application, and not of all embodiments of the application, unless the detailed description explicitly indicates otherwise, and readers of the specification should not make implications to the contrary.

FIG. 1A illustrates a cross-sectional view of a semiconductor package according to an embodiment of the present application.

FIG. 1B illustrates a top view of the semiconductor package shown in FIG. 1A.

FIGS. 1C to 1D illustrate cross-sectional views of semiconductor packages according to various embodiments of the present application.

FIGS. 2A to 2G illustrate cross-sectional views of steps of forming a semiconductor package according to an embodiment of the present application.

FIGS. 3A to 3E illustrate cross-sectional views of steps of forming a semiconductor package according to another embodiment of the present application.

FIGS. 4A to 4G illustrate cross-sectional views of steps of forming a semiconductor package according to another embodiment of the present application.

FIGS. 5 to 7 illustrate cross-sectional views of semiconductor packages according to various embodiments of the present application.

The same reference numbers will be used throughout the drawings to refer to the same or like parts.

### DETAILED DESCRIPTION OF THE INVENTION

The following detailed description of exemplary embodiments of the application refers to the accompanying drawings that form a part of the description. The drawings illustrate specific exemplary embodiments in which the application may be practiced. The detailed description, including the drawings, describes these embodiments in sufficient detail to enable those skilled in the art to practice the application. Those skilled in the art may further utilize other embodiments of the application, and make logical, mechanical, and other changes without departing from the spirit or scope of the application. Readers of the following detailed description should, therefore, not interpret the description in a limiting sense, and only the appended claims define the scope of the embodiment of the application.

In this application, the use of the singular includes the plural unless specifically stated otherwise. In this application, the use of “or” means “and/or” unless stated otherwise. Furthermore, the use of the term “including” as well as other forms such as “includes” and “included” is not limiting. In addition, terms such as “element” or “component” encompass both elements and components including one unit, and elements and components that include more than one subunit, unless specifically stated otherwise. Additionally, the section headings used herein are for organizational purposes only, and are not to be construed as limiting the subject matter described.

As used herein, spatially relative terms, such as “beneath”, “below”, “above”, “over”, “on”, “upper”, “lower”, “left”, “right”, “vertical”, “horizontal”, “side” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The device may be otherwise oriented (rotated 90 degrees or at other orientations) and the spatially relative descriptors used herein may likewise be interpreted accordingly. It should be understood that when an element is referred to as being “connected to” or “coupled to” another element, it may be directly connected to or coupled to the other element, or intervening elements may be present.

In the semiconductor industry, it is desired to integrate more and more electronic components in a single package. The present application provides a semiconductor package with improved spatial efficiency and production efficiency.

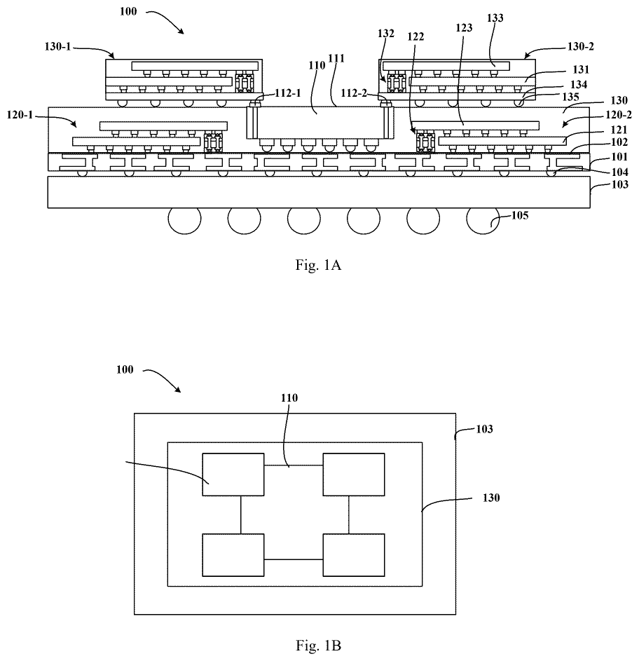

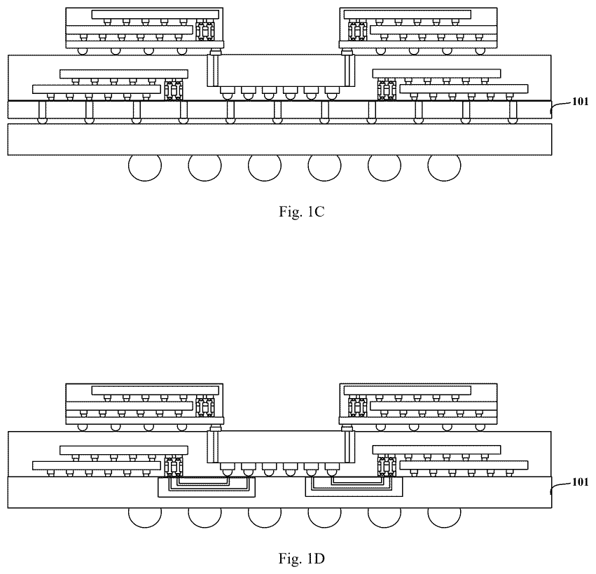

FIG. 1A illustrates a cross-sectional view of a semiconductor package 100 according to an embodiment of the present application. FIG. 1B illustrates a top view of the semiconductor package 100 shown in FIG. 1A.

Referring to FIG. 1A, the semiconductor package 100 includes a substrate 101 where various electronic components are mounted. For example, a base semiconductor die 110 and at least one, such as two first semiconductor components 120-1, 120-2 are mounted on the substrate 101, and an encapsulant layer 130 is formed on the substrate 101 to encapsulate the first semiconductor components 120-1, 120-2 and the base semiconductor die 110, and at least one, such as two second semiconductor components 130-1, 130-2. In some embodiments, the substrate 101 is further mounted on a package substrate 103, which may provide structural support and routing to the electronic components on the package substrate 103. In some embodiments, the package substrate 103 may be further equipped with solder balls 105 so that the semiconductor package 100 can be mounted to an external platform or device.

Specifically, the substrate 101 includes a plurality of substrate interconnection structures 102 for providing electrical connections between electronic components mounted thereon. In some embodiments, the substrate 101 is a redistribution layer interposer. In some embodiments, the substrate 101 may include one or more insulating or passivation layers (not shown) and one or more substrate interconnection structures 102 formed in the insulating or passivation layers. Each substrate interconnection structure 102 may include one or more conductive vias formed through the insulating or passivation layers, and one or more conductive layers formed on a top surface and/or a bottom surface of the substrate 101. The substrate 101 may include one or more laminated layers of polytetrafluoroethylene pre-impregnated, FR-4, FR-1, CEM-1, or CEM-3 with a combination of phenolic cotton paper, epoxy, resin, woven glass, matte glass, polyester, and other reinforcement fibers or fabrics. The substrate 101 can also be a multi-layer flexible laminate, ceramic, copper clad laminate, or glass. In some embodiments, the substrate interconnection structures 102 or redistribution layers (RDL) inside the substrate 101 can be formed using sputtering, electrolytic plating, electroless plating, or other suitable deposition process. The conductive vias and layers may be one or more layers of Al, Cu, Sn, Ni, Au, Ag, titanium (Ti), tungsten (W), or other suitable electrically conductive material.

The base semiconductor die 110 is mounted on the substrate 101. The base semiconductor die 110 includes a plurality of through vias 112-1, 112-2 at a periphery of the base semiconductor die 110, which extend between a top surface 111 and a bottom surface of the base semiconductor die 110 to form respective electrical paths through the base semiconductor die 110. Each of the plurality of through vias 112-1, 112-2 is electrically coupled to the substrate 101, for example, to one or some of the plurality of substrate interconnection structures 102. In some embodiments, solder balls (not shown) are arranged beneath the through vias 112-1, 112-2 on the substrate 101, such that the through vias can be electrically coupled to the substrate 101 vias solder balls. In some embodiments, through vias 112-1, 112-2 may be coupled to redistribution layer (not shown) at the bottom of the base semiconductor die 110, wherein the redistribution layer is further disposed with solder balls underneath the redistribution layer for electrical connection between the base semiconductor die 110 and external electronic component, such as the substrate 101. Thus, the through vias 112-1, 112-2 may be electrically coupled to the substrate 101 via redistribution layer and solder balls.

In some embodiments, the plurality of through vias 112-1, 112-2 are at four corners of the base semiconductor die 110. In some embodiments, the plurality of through vias 112-1, 112-2 are also arranged near a center of each edge of the base semiconductor die 110. Such layout of the through vias 112-1, 112-2 at the periphery of the base semiconductor die 110 may facilitate multiple electrical connections from the base semiconductor die 110 to other electronic components, and/or reserve space for heat dissipation from the top surface 111 of the base semiconductor die 110 to the external environment.

Still referring to FIG. 1A, the first semiconductor components 120-1, 120-2 are disposed beside the base semiconductor die 110 and on the substrate 101. In particular, the base semiconductor die 110 is electrically connected to the first semiconductor components 120-1, 120-2 via the substrate interconnection structures 102, which are both encapsulated by the encapsulant layer 130. In order to arrange other electronic components on top of the encapsulant layer 130, the encapsulant layer 130 may be formed to expose the top surface 111 of the base semiconductor die 110. Therefore, the plurality of through vias 112-1, 112-2 of the base semiconductor die 110 are exposed at the top surface 111 for further electrical connection.

In some embodiments, the encapsulant layer 130 can be a polymer composite material, such as epoxy resin, epoxy acrylate, or any suitable polymer with or without filler. The encapsulant layer 130 may be non-conductive, provide structural support, and environmentally protect the electronic devices therein from external environment and contaminants. The encapsulant layer 130 may be formed with any shape as desired. The encapsulant layer 130 may be formed by depositing an encapsulant or molding compound on the substrate 101 using injection molding, compressive molding, transfer molding, liquid encapsulant molding, vacuum lamination, spin coating, or another suitable processes.

Furthermore, the second semiconductor components 130-1 and 130-2 are disposed on top of the encapsulant layer 130. Specifically, the second semiconductor components 130-1 and 130-2 are disposed on the top surface 111 of the base semiconductor die 110 and the encapsulant layer 130, and the second semiconductor components 130-1 and 130-2 are in contact with the plurality of through vias 112-1, 112-2 exposed at the top surface 111 of the base semiconductor die 110, e.g., through a solder material. Thus, the second semiconductor components 130-1 and 130-2 are electrically coupled to the substrate 101 through at least one of the plurality of through vias 112-1 and 112-2.

Preferably, the base semiconductor die 110 is a system-on-chip die formed with the plurality of through silicon vias (TSVs) 112-1, 112-2 at corners of the base semiconductor die 110. Each of the first semiconductor components 120-1, 120-2 includes a first semiconductor die 121 mounted on the substrate 101, an interconnection block 122 disposed beside the first semiconductor die 121 on the substrate 101, and a second semiconductor die 123. Moreover, the second semiconductor die 123 is disposed partially on the first semiconductor die 121 and partially on the interconnection block 122, and the second semiconductor die 123 is electrically coupled to the interconnection block 122. Since the interconnection block 122 is electrically coupled to the substrate 101, the second semiconductor die 123 is also electrically coupled to the substrate 101 and any other electronic components that are electrically coupled thereto. Preferably, each of the first semiconductor die 121 and the second semiconductor die 123 is a memory die. In some embodiments, the memory die may have a big size but not generate significant heat compared with the base semiconductor die 110, such as a data processor, a controller or other similar circuits. Therefore, such layout utilizes the space beside and above the base semiconductor die 110 efficiently, while the heat dissipation of the base semiconductor die 110 remains optimal.

Preferably, similar to the configuration of the first semiconductor components 120-1, 120-2, the second semiconductor components 130-1, 130-2 may also include semiconductor dice, such as memory dice 131, 133 and an interconnection block 132 that connects the two. Different from the first semiconductor components 120-1, 120-2, the second semiconductor components 130-1, 130-2 may be pre-formed with respective base substrates 134 for accommodating the semiconductor dice 131, 133 and the interconnection block 132 thereon. The configuration of the base substrates 134 and the second semiconductor components 130-1, 130-2 may not be repeated herein. Furthermore, the second semiconductor components 130-1, 130-2 may be mounted on the encapsulant layer 130 via such as solder balls 135. Specifically, at least one of the solder balls 135 may be in direct contact with the through vias 112-1, 112-2 at the top surface of the base semiconductor die 110. Therefore, the electronic components of the second semiconductor components 130-1, 130-2, i.e., semiconductor dice 131, 133 and the interconnection block 132, may be electrically coupled to the base substrate 134, the solder balls 135, the through vias 112-1, 112-2 of the base semiconductor die 110, and therefore to the substrate 101 and other electronic component electrically coupled to the substrate 101. Therefore, with such a layout shown in FIG. 1A, the system-on-chip die 110 may be integrated with multiple stacked memory dice with a compact structure and high spatial efficiency.

FIG. 1B illustrates a top view of the semiconductor package 100 shown in FIG. 1A. As can be seen, the encapsulant layer 130 may occupy an area smaller or equal to that of the substrate 103, and the base semiconductor die 110 may be surrounded by the encapsulant layer 130. In some embodiments, the second semiconductor component 130 may partially overlap with of the base semiconductor die 110 when viewed from the top of the semiconductor package 100. Preferably, as shown in FIG. 1B, each of the second semiconductor components 130 may overlap with one corner of the base semiconductor die 110 and thus does not conflict with the others of the second semiconductor components 130. Preferably, a proportion between an overlapping area of the base semiconductor die 110 and a total area of the top surface of the base semiconductor die 110 is between 10% to 50%, to release a compact structure.

It can be understood that variations can be made to the electronic components mentioned above. In some other embodiments, the interconnection blocks 122, 132 may be an e-bar block or a silicon or other semiconductor interposer block, and the solder balls 135 may be replaced by one or more Cu posts beneath the base substrate 134 for electrical connection. It can be understood that, in some embodiments, some solder balls or Cu posts 135 may be used for electrical connection with the through vias 112-1, 112-2, while some other solder balls or Cu posts 135 may be dummy structures and are used mainly for providing structural support for the respective second semiconductor components 130-1, 130-2.

FIGS. 1C and 1D show two variations of the substrate 101 shown in FIG. 1A. Referring to FIG. 1C, the substrate 101 may be a silicon interposer, which may be mounted on another substrate. Referring to FIG. 1D, the substrate 101 may be integrated with one or more embedded multi-die interconnect bridges (EMIB). Both the silicon interposer and the EMIB substrate provide electrical connection for electronic components mounted thereon.

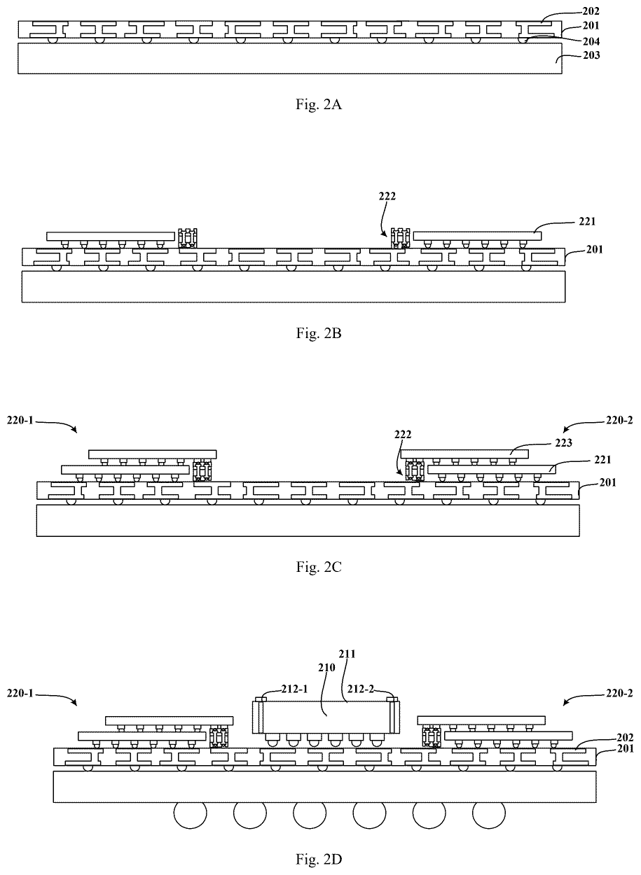

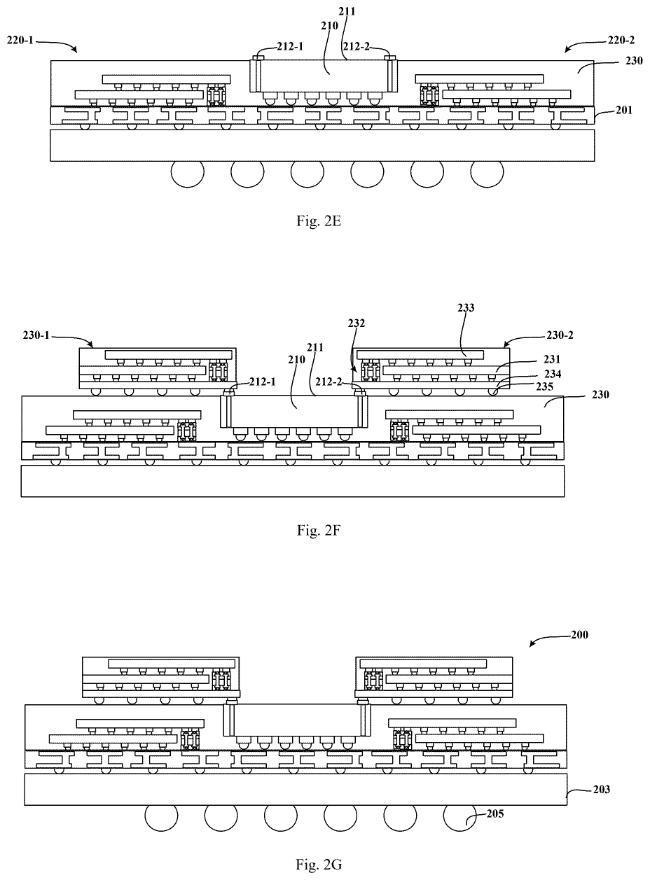

FIGS. 2A to 2G illustrate cross-sectional views of steps of a method for forming a semiconductor package 200 according to an embodiment of the present application. It can be understood that, the method can be used to form the semiconductor package 100 shown in FIGS. 1A and 1B.

Referring to FIG. 2A, a substrate 201 with various internal substrate interconnection structures 202 is provided. In some embodiments, the substrate 201 is mounted on a package substrate 203 via solder balls 204 for electrically coupling the package to be formed with other electronic components on the package substrate 203.

Referring to FIGS. 2B and 2C, after the substrate is provided, at least one first semiconductor component 220-1, 220-2 can be mounted on the substrate 201. In some embodiments, the at least one first semiconductor component 220-1, 220-2 may include a first semiconductor die 221, an interconnection block 222 and a second semiconductor die 223.

Specifically, referring to FIG. 2B, at least one pair of first semiconductor die 221 and interconnection block 222 can be mounted on the substrate 201. For example, the interconnection block 222 is disposed beside the first semiconductor die 221 that is paired with the interconnection block 222. Preferably, space at a center of the substrate 201 may be reserved for further mounting a base semiconductor die as illustrated below.

Referring to FIG. 2C, the second semiconductor dice 223 are mounted on the respective first semiconductor dice 221 and interconnection blocks 222. In particular, one of the second semiconductor dice 223 may be disposed partially on the corresponding first semiconductor die 221 and partially on the corresponding interconnection block 222. Each second semiconductor die 223 is electrically coupled to the respective interconnection block 222 and therefore electrically coupled to the substrate 201, such that each second semiconductor die 223 may be electrically coupled to other electronic components on the substrate 201.

Referring to FIG. 2D, after the first semiconductor components 220-1, 220-2 are mounted, a base semiconductor die 210 can be further mounted on the substrate 201. Herein, the first semiconductor components 220-1, 220-2 are disposed beside the base semiconductor die 210. Preferably, the base semiconductor die 210 is disposed at the center of the substrate 201. Specifically, the base semiconductor die 210 is electrically coupled to the substrate interconnection structures 202 of the substrate 201, and is therefore electrically coupled to the first semiconductor components 220-1 and 220-2. The base semiconductor die 210 may include a plurality of through vias 212-1, 212-2 that are pre-formed at a periphery of the base semiconductor die 210. The plurality of through vias 212-1, 212-2 extend between a top surface 211 and a bottom surface of the base semiconductor die 210, and is electrically coupled to the substrate 201. The plurality of through vias 212-1, 212-2 are used for providing electrical connection for other electronic components on the base semiconductor die 210. The layout that the through vias 212-1, 212-2 are at the periphery of the base semiconductor die 210 advantageously allows other electronic components to be electrically coupled to the base semiconductor die 210 from the external of the base semiconductor die 210 while a top surface 211 of the base semiconductor die 210 is reserved for other components or for heat dissipation. It can be understood that, in some other embodiments, the base semiconductor die 210 can be first mounted, and the first semiconductor components 220-1, 220-2 can then be mounted.

Referring to FIG. 2E, an encapsulant layer 230 is formed on the substrate 201 to encapsulate the first semiconductor component 220-1, 220-2 and the base semiconductor die 210 but expose the top surface 211 of the semiconductor die 210. Therefore, the plurality of through vias 212-1, 212-2 may be exposed from the encapsulant layer 230 for providing further electrical connection to additional electronic components or structures that may be subsequently mounted on the encapsulant layer 230. The encapsulant layer 230 may be formed by depositing an encapsulant or molding compound on the substrate 201 using injection molding, compressive molding, transfer molding, liquid encapsulant molding, vacuum lamination, spin coating, or another suitable processes.

Referring to FIG. 2F, at least one, such as two second semiconductor components 230-1, 230-2 are mounted on the base semiconductor die 210 and on the encapsulant layer 230 to electrically couple each of the second semiconductor components 230-1, 230-2 with at least one of the plurality of through vias 212-1, 212-2 of the base semiconductor die 210.

In some embodiments, each of the second semiconductor components 230-1, 230-2 may be pre-formed as a package. Specifically, in some embodiments, each of the second semiconductor components 230-1, 230-2 may be formed by mounting a first semiconductor die 231 and an interconnection block 232 on a base substrate 234, and the interconnection block 232 may be disposed beside the first semiconductor die 231. Then a second semiconductor die 233 can be mounted on the first semiconductor die 231 and the interconnection block 232, and the second semiconductor die 233 may be disposed partially on the first semiconductor die 231 and partially on the interconnection block 232. Therefore, the second semiconductor die 233 is electrically connected to the interconnection block 232 and the base substrate 234. Further, the first semiconductor die 231, the interconnection block 232 and the second semiconductor die 233 can be encapsulated with an encapsulant compound and thus form an integrate piece or unit. It can be appreciated that the formation of the at least one second semiconductor component 230-1, 230-2 can be achieved at a wafer-level, and each second semiconductor component 230-1, 230-2 can be singulated from a wafer with various units or cells.

After the formation of the second semiconductor components 230-1, 230-2, the base substrate 234 of the second semiconductor components 230-1, 230-2 can be mounted on the encapsulant layer 230, preferably via a plurality of solder balls 235. At least one of the plurality of solder balls 235 is disposed on and electrically coupled to at least one of the plurality of through vias 212-1 and 212-2 at the top surface 211 of the semiconductor die 210.

Referring to FIG. 2G, in some embodiments, the package substrate 203 may be formed with solder balls 205 for further electrical connection. Thus, the semiconductor package 200 is so formed.

As can be seen, the method allows for accommodating multiple sets of stacked memories in a single package. The space around a semiconductor die can be efficiently used, and therefore a height of the whole package can be controlled or reduced. In the previous steps, the at least one semiconductor components can be packaged at once with the base semiconductor die, and therefore, they can also be tested together, which can be cost saving.

It can be understood that variations can be made to the first semiconductor components 220-1, 220-2. Similar as the second semiconductor components 230-1, 230-2, in some embodiments, the first semiconductor components 220-1, 220-2 can also take the form of a pre-formed package as illustrated below.

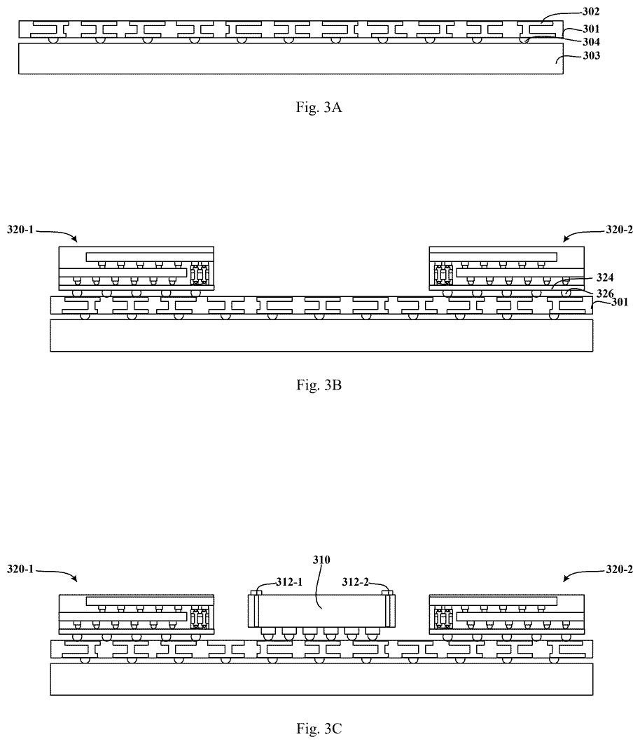

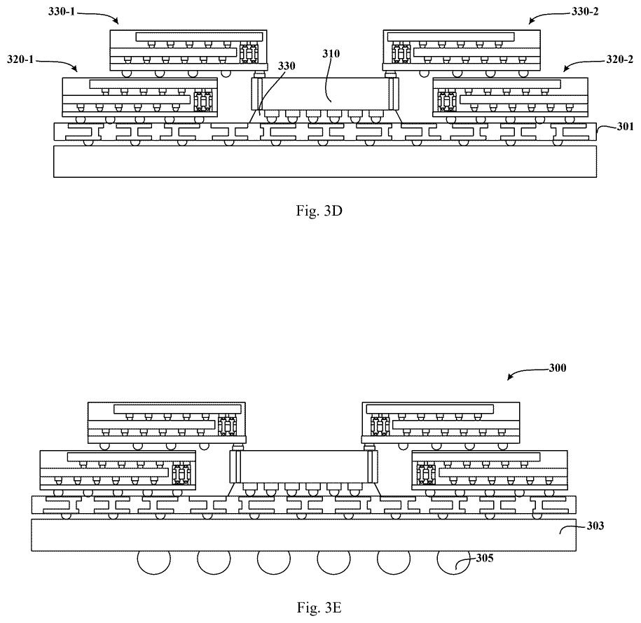

FIGS. 3A to 3E illustrate cross-sectional views of steps of forming a semiconductor package 300 according to another embodiment of the present application.

Referring to FIG. 3A, a substrate 301 with substrate interconnection structures 302 is provided. In some embodiments, the substrate 301 may be mounted on a package substrate 303 via solder balls 304.

Referring to FIG. 3B, at least one, such as two first semiconductor component 320-1, 320-2 can be mounted on the substrate 301. Each of the first semiconductor components 320-1, 320-2 can be a pre-formed package with multiple semiconductor dice mounted on a base substrate 324. The first semiconductor components 320-1, 320-2 may be mounted on and electrically coupled to the substrate 301 via such as solder balls 326.

Referring to FIG. 3C, the base semiconductor die 310 with a plurality of through vias 312-1, 312-2 can then be mounted beside the first semiconductor components 320-1, 320-2. Preferably, a height of the base semiconductor die 310 is the same as that of the first semiconductor components 320-1, 320-2, such that their top surfaces may together form a flat plane for mounting further electronic components.

Referring to FIG. 3D, in some embodiments, an encapsulant layer 330 can be formed at least at a foot portion of the base semiconductor die 310 on the substrate 301, such that the base semiconductor die can be stable in structure. In some other embodiments, an encapsulant layer 330 can be further formed to fully encapsulate the base semiconductor die 310, with or without the first semiconductor components 320-1, 320-2. The second semiconductor components 330-1 and 330-2 are mounted on top of the base semiconductor die 310 and the first semiconductor components 320-1, 320-2.

Referring to FIG. 3E, additional solder balls 305 may be mounted to the package substrate 303. Thus, the semiconductor package 300 is so formed.

It can be understood that, in the previous steps, since the first semiconductor components 320-1, 320-2 and the second semiconductor components 330-1, 330-2 can be pre-formed packages with the same or similar structures, they can be manufactured as modules which can then be mounted onto the substrate. In this way, the manufacture efficiency for forming semiconductor packages can be improved.

It can be understood that the abovementioned substrate may take various forms such as a redistribution layer interposer, a silicon interposer or a substrate integrated with EMIB.

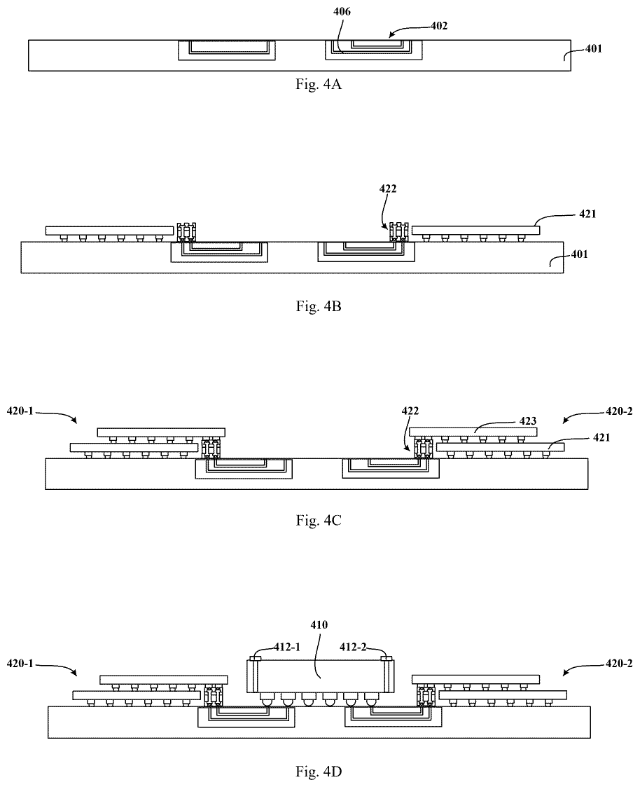

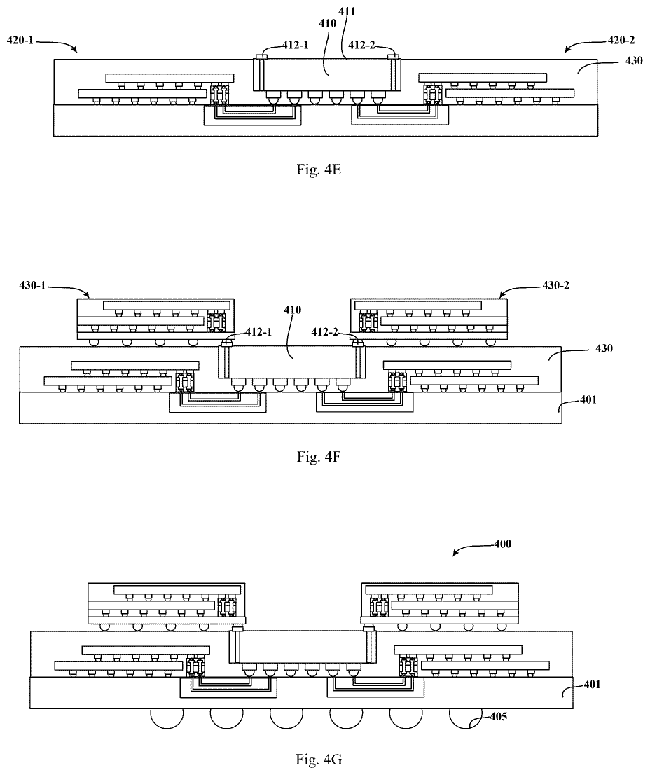

FIGS. 4A to 4G illustrate cross-sectional views of steps of forming a semiconductor package 400 according to another embodiment of the present application.

Referring to FIG. 4A, in some embodiments, the substrate 401 may be a substrate 401 integrated with one or more EMIBs 402. In each EMIB 402, one or more interconnection bridges 406 may provide lateral electrical connection between electronic components both mounted on the substrate 401.

Referring to FIGS. 4B and 4C, interconnection blocks 422, first semiconductor dice 421 and second semiconductor dice 422 are mounted on the substrate 401, together forming each of the first semiconductor components 420-1 and 420-2.

Referring to FIGS. 4D and 4E, a base semiconductor die 410 with a plurality of through vias 412-1, 412-2 is disposed beside the first semiconductor components 420-1 and 420-2, and then they are encapsulated together by an encapsulant layer 430. The encapsulant layer 430 may be formed to expose a top surface 411 of the base semiconductor die 410, such that the through vias 412-1, 412-2 are exposed.

Referring to FIG. 4F, the second semiconductor components 430-1 and 430-2 are mounted on the encapsulant layer 430. The second semiconductor components 430-1 and 430-2 are electrically coupled to the through vias 412-1, 412-2 of the base semiconductor die 410, and are therefore electrically coupled to the substrate 401.

Referring to FIG. 4G, the substrate 401 may be mounted with solder balls 405 for electrical connection outside the semiconductor package 400.

It can be understood that although in the previous cross-sectional views, only two base semiconductor dice, two first semiconductor components and two second semiconductor components are shown, in other embodiments, other numbers of base semiconductor dice, first semiconductor components or second semiconductor components can be integrated within the semiconductor package so formed.

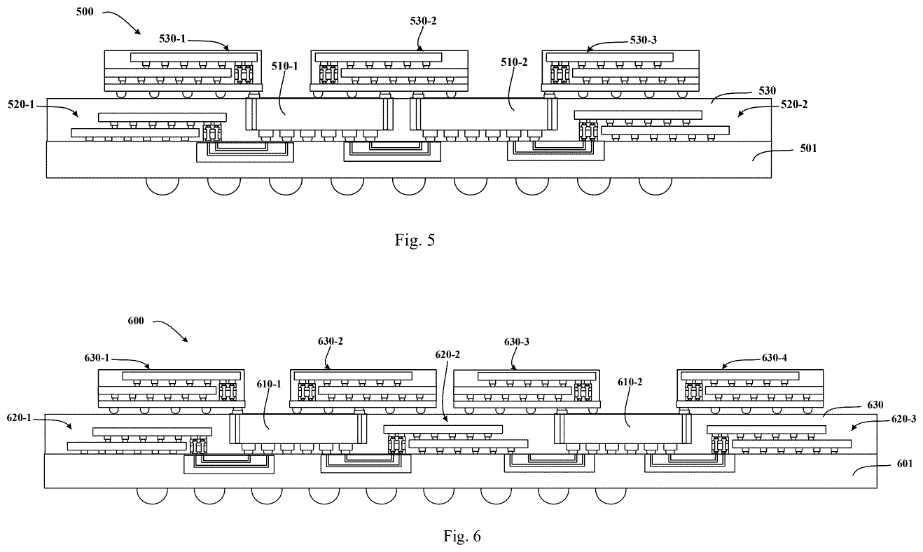

FIGS. 5 to 7 illustrate cross-sectional views of semiconductor packages according to various embodiments of the present application.

Referring to FIG. 5, a semiconductor package 500 may include multiple base semiconductor dice 510-1 and 510-2 integrated with at least one, such as two first semiconductor components 520-1 and 520-2. The multiple base semiconductor dice 510-1 and 510-2 are disposed together in a central region of the substrate 501. Three second semiconductor components 530-1, 530-2 and 530-3 can be mounted on an encapsulant layer 530 which encapsulates the underneath components. For example, the second semiconductor component 530-2 may be electrically coupled to both the base semiconductor dice 510-1 and 510-2.

It can be understood that the multiple base semiconductor dice can also adopt other layouts. For example, other electronic components such as a first semiconductor component may be disposed in-between the multiple base semiconductor dice.

Referring to FIG. 6, a semiconductor package 600 may include multiple base semiconductor dice 610-1 and 610-2, which are mounted in parallel with at least one, such as three first semiconductor components 620-1, 620-2 and 620-3 on a substrate 601. In some embodiments, the first semiconductor component 620-2 may be disposed between the base semiconductor dice 610-1 and 610-2, while the other first semiconductor components 620-1 and 620-3 are disposed closer to the outer periphery with respect to the base semiconductor dice 610-1 and 610-2. Since the semiconductor package 600 has a wider area, more second semiconductor components 630-1 to 630-4 may be mounted on the encapsulant layer 630.

It can be understood that the semiconductor package according to some embodiments of the present application may be further equipped with a heat spreader for dissipating heat generated from the multiple semiconductor component to the external space.

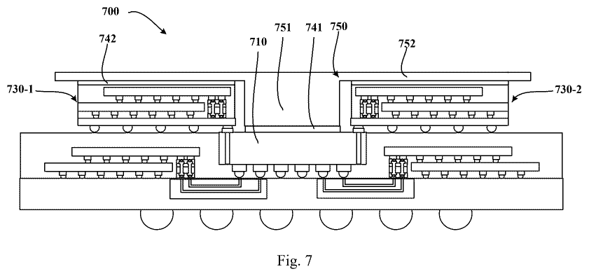

Referring to FIG. 7, a heat spreader 750 may be disposed on the base semiconductor die 710 and the second semiconductor components 730-1, 730-2. The heat spreader 750 may have a shape generally in conformity with that of the base semiconductor die 710 and the second semiconductor components 730-1, 730-2, such that the heat spreader 750 can provide a larger contact area for these components. In some embodiments, the heat spreader 750 includes a bottom portion 751 and a top portion 752. Specifically, the bottom portion 751 is disposed on the top surface of the base semiconductor die 710 and extends between the second semiconductor components 730-1, 730-2. Furthermore, the top portion 752 is disposed on the bottom portion 751 and the second semiconductor components 730-1, 730-2. In some embodiments, the top portion 752 may extend beyond the second semiconductor components 730-1, 730-2 to provide larger area for heat dissipation. In some embodiments, the bottom portion 751 of the heat spreader 750 is thermally coupled to the base semiconductor die 710 via a thermal interface material layer 741. The top portion 752 of the heat spreader 750 is thermally coupled to the second semiconductor components 730-1, 730-2 via an adhesive layer 742.

The discussion herein included numerous illustrative figures that showed various steps in a method of making a semiconductor package. For illustrative clarity, such figures did not show all aspects of each example assembly. Any of the example assemblies and/or methods provided herein may share any or all characteristics with any or all other assemblies and/or methods provided herein.

Various embodiments have been described herein with reference to the accompanying drawings. It will, however, be evident that various modifications and changes may be made thereto, and additional embodiments may be implemented, without departing from the broader scope of the invention as set forth in the claims that follow. Further, other embodiments will be apparent to those skilled in the art from consideration of the specification and practice of one or more embodiments of the invention disclosed herein. It is intended, therefore, that this application and the examples herein be considered as exemplary only, with a true scope and spirit of the invention being indicated by the following listing of exemplary claims.

1. A semiconductor package, comprising:
a substrate comprising a substrate interconnection structure;
a base semiconductor die comprising a plurality of through vias at a periphery of the base semiconductor die and extending between a top surface and a bottom surface of the base semiconductor die, wherein each of the plurality of through vias is electrically coupled to the substrate;
at least one first semiconductor component disposed beside the base semiconductor die and on the substrate, wherein the base semiconductor die is electrically connected to the at least one first semiconductor component via the substrate interconnection structure;
an encapsulant layer for encapsulating the at least one first semiconductor component and the base semiconductor die but exposing the top surface of the base semiconductor die; and
at least one second semiconductor component each being disposed on the top surface of the base semiconductor die and the encapsulant layer, and electrically coupled to the substrate through at least one of the plurality of through vias.

2. The semiconductor package of claim 1, wherein each semiconductor component of the at least one first semiconductor component and the at least one second semiconductor component comprises:
a first semiconductor die;
an interconnection block disposed beside the first semiconductor die; and
a second semiconductor die, wherein the second semiconductor die is disposed partially on the first semiconductor die and partially on the interconnection block, and wherein the second semiconductor die is electrically coupled to the interconnection block.

3. The semiconductor package of claim 2, wherein each semiconductor component of the at least one second semiconductor component is a semiconductor package.

4. The semiconductor package of claim 2, wherein each of the first semiconductor die and the second semiconductor die is a memory die.

5. The semiconductor package of claim 1, wherein each of the plurality of through vias is at a corner of the base semiconductor die.

6. The semiconductor package of claim 1, further comprising: a heat spreader disposed on the base semiconductor die and the at least one second semiconductor component, wherein the heat spreader comprises a bottom portion and a top portion, wherein the bottom portion is disposed on the top surface of the base semiconductor die and extends between the at least one second semiconductor component, and the top portion is disposed on the bottom portion and the at least one second semiconductor component.

7. The semiconductor package of claim 1, wherein the at least one second semiconductor component partially overlaps with the top surface of the base semiconductor die, wherein a proportion between an overlapping area of the base semiconductor die and a total area of the top surface of the base semiconductor die is between 10% to 50%.

8. A method for making a semiconductor package, comprising:
providing a substrate, wherein the substrate comprises a substrate interconnection structure;
mounting at least one first semiconductor component on the substrate;
mounting a base semiconductor die on the substrate and beside the at least one first semiconductor component to electrically couple the base semiconductor die with the at least one first semiconductor component via the substrate interconnection structure, wherein the base semiconductor die comprises a plurality of through vias at a periphery of the base semiconductor die and extending between a top surface and a bottom surface of the base semiconductor die;
forming an encapsulant layer on the substrate to encapsulate the at least one first semiconductor component and the base semiconductor die but expose the top surface of the semiconductor die; and
mounting at least one second semiconductor component on the base semiconductor die and on the encapsulant layer to electrically couple the at least one second semiconductor component with the base semiconductor die through at least one of the plurality of through vias.

9. The method of claim 8, wherein mounting at least one first semiconductor component on the substrate comprises:
mounting a first semiconductor die and an interconnection block on the substrate, wherein the interconnection block is disposed beside the first semiconductor die; and
mounting a second semiconductor die on the first semiconductor die and the interconnection block, wherein the second semiconductor die is disposed partially on the first semiconductor die and partially on the interconnection block, and wherein the second semiconductor die is electrically coupled to the interconnection block.

10. The method of claim 8, wherein mounting at least one first semiconductor component on the substrate comprises:
providing a base substrate;
mounting a first semiconductor die and an interconnection block on the base substrate, wherein the interconnection block is disposed beside the first semiconductor die; and
mounting a second semiconductor die on the first semiconductor die and the interconnection block, wherein the second semiconductor die is disposed partially on the first semiconductor die and partially on the interconnection block, and wherein the second semiconductor die is electrically connected to the interconnection block; and
encapsulating the first semiconductor die, the interconnection block and the second semiconductor die; and
mounting the base substrate on the substrate via a plurality of solder balls, wherein at least one of the plurality of solder balls is disposed on and electrically coupled to the substrate interconnection structure.

11. The method of claim 8, wherein mounting at least one second semiconductor component comprises:
providing a base substrate;
mounting a first semiconductor die and an interconnection block on the base substrate, wherein the interconnection block is disposed beside the first semiconductor die; and
mounting a second semiconductor die on the first semiconductor die and the interconnection block, wherein the second semiconductor die is disposed partially on the first semiconductor die and partially on the interconnection block, and wherein the second semiconductor die is electrically connected to the interconnection block; and
encapsulating the first semiconductor die, the interconnection block and the second semiconductor die; and
mounting the base substrate on the encapsulant layer via a plurality of solder balls, wherein at least one of the plurality of solder balls is disposed on and electrically coupled to at least one of the plurality of through vias at the top surface of the semiconductor die.

12. The method of claim 9, wherein each of the first semiconductor die and the second semiconductor die is a memory die.

13. The method of claim 10, wherein each of the first semiconductor die and the second semiconductor die is a memory die.

14. The method of claim 11, wherein each of the first semiconductor die and the second semiconductor die is a memory die.

15. The method of claim 8, wherein each of the plurality of through vias is at a corner of the base semiconductor die.

16. The method of claim 8, further comprising: disposing a heat spreader on the base semiconductor die and the at least one second semiconductor component, wherein the heat spreader comprises a bottom portion and a top portion, wherein the bottom portion is disposed on the top surface of the base semiconductor die and extends between the at least one second semiconductor component, and the top portion is disposed on the bottom portion and the at least one second semiconductor component.

17. The method of claim 8, wherein mounting at least one second semiconductor component on the base semiconductor die and on the encapsulant layer comprises: partially overlapping the at least one second semiconductor component with the top surface of the base semiconductor die, wherein a proportion between an overlapping area of the base semiconductor die and a total area of the top surface of the base semiconductor die is between 10% to 50%.
